(19) United States
(12) Patent Application Publication
(10) Pub. No.: US 2025/0379141 A1
(43) Pub. Date: Dec. 11, 2025

(54) METAL VIA WITH DUAL PARTIAL LINER

(71) Applicant: International Business Machines Corporation, Armonk, NY (US)

(72) Inventors: Oscar van der Straten, Guilderland Center, NY (US); Chih-Chao Yang, Glenmont, NY (US)

(21) Appl. No.: 18/735,952

(22) Filed: Jun. 6, 2024

(51) Int. Cl. H01L 23/522; H01L 21/768; H01L 23/532

(52) U.S. Cl. CPC H01L 23/5226; H01L 21/76846; H01L 23/53238; H01L 23/53252

(57) ABSTRACT

An interconnect structure is provided that includes an electrically conductive via which includes a dual partial liner located along a portion of a sidewall of the via. The electrically conductive via is in direct physical contact with an underlying electrically conductive structure. The presence of the dual partial liner reduces the via resistance of the interconnect structure containing the same.

### BACKGROUND

The present application relates to semiconductor technology, and more particularly to an interconnect structure including a dual partial liner located on a sidewall of an electrically conductive via.

Generally, semiconductor devices include a plurality of circuits which form an integrated circuit fabricated on a semiconductor substrate. A complex network of signal paths will normally be routed to connect the circuit elements distributed on the surface of the substrate. Efficient routing of these signals across the device requires formation of multilevel or multilayered schemes, such as, for example, single or dual damascene wiring, i.e., interconnect, structures.

Within typical interconnect structures, electrically conductive metal vias run perpendicular to the semiconductor substrate and electrically conductive metal lines run parallel to the semiconductor substrate. Typically but not necessarily always, an electrically conductive metal via is present beneath an electrically conductive metal line and both features are embedded within an interlayer dielectric material layer.

### SUMMARY

An interconnect structure is provided that includes an electrically conductive via which includes a dual partial liner located along a portion of a sidewall of the via. The electrically conductive via is in direct physical contact with an underlying electrically conductive structure. The presence of the dual partial liner reduces the via resistance of the interconnect structure containing the same.

In one embodiment of the present application, the interconnect structure includes an electrically conductive structure embedded in a first interlayer dielectric layer, an electrically conductive via embedded in a second interlayer dielectric layer in which the electrically conductive via is in direct physical contact with the electrically conductive structure, and a dual partial liner located on a portion of a sidewall of the electrically conductive via. In this embodiment, the dual partial liner includes a first partial liner and a second partial liner in which the first partial liner extends under the second partial liner and the electrically conductive via structure extends over both the first partial liner and the second partial liner and contacts a sidewall of the second interlayer dielectric layer.

In another embodiment of the present application, the interconnect structure includes an electrically conductive structure embedded in a first interlayer dielectric layer, an electrically conductive via embedded in a second interlayer dielectric layer in which the electrically conductive via is in direct physical contact with the electrically conductive structure, and a dual partial liner located on a portion of a sidewall of the electrically conductive via. In this embodiment, the dual partial liner includes a first partial liner and a second partial liner in which the first partial liner extends under the second partial liner and has a topmost surface that is substantially coplanar with a topmost surface of the second partial liner.

In a further embodiment of the present application, the interconnect structure includes an electrically conductive structure embedded in a first interlayer dielectric layer, an electrically conductive via embedded in a second interlayer dielectric layer in which the electrically conductive via is in direct physical contact with the electrically conductive structure, and a dual partial liner located on a portion of a sidewall of the electrically conductive via. In this embodiment, the dual partial liner includes a first partial liner and a second partial liner in which the first partial liner extends under the second partial liner and has a topmost surface that is vertically offset and located above a topmost surface of the second partial liner.

### BRIEF DESCRIPTION OF THE DRAWINGS

FIG. 1 is a cross sectional view of an exemplary structure that can be employed in the present application, the exemplary structure including an electrically conductive structure embedded in a first interlayer dielectric (ILD) layer, and a dielectric cap located on the first ILD layer and the electrically conductive structure.

FIG. 2 is a cross sectional view of the exemplary structure of FIG. 1 after forming a second ILD layer on the dielectric cap.

FIG. 3 is a cross sectional view of the exemplary structure of FIG. 2 after forming a via opening in the second ILD layer.

FIG. 4 is a cross sectional view of the exemplary structure of FIG. 3 after performing a dielectric cap punch through etch to extend the via opening such that an extended via opening is formed that physically exposes a portion of the electrically conductive structure.

FIG. 5 is a cross sectional view of the exemplary structure of FIG. 4 after depositing a first liner material layer in the extended via opening and on a topmost surface of the second ILD layer.

FIG. 6 is a cross sectional view of the exemplary structure of FIG. 5 after depositing a second liner material layer on the first liner material layer.

FIG. 7 is a cross sectional view of the exemplary structure of FIG. 6 after performing an etch back process on the second liner material layer and the first liner material layer to re-expose a portion of the electrically conductive structure.

FIG. 8 is a cross sectional view of the exemplary structure of FIG. 7 after depositing a first electrically conductive metal-containing layer in the extended via opening and above the topmost surface of the second ILD layer.

FIG. 9 is a cross sectional view of the exemplary structure of FIG. 8 after performing a planarization process to remove the first electrically conductive metal-containing layer, the second liner material layer and the first liner material layer from above the topmost surface of the second ILD layer and to provide a first electrically conductive via, a second liner and a first liner, respectively in the extended via opening.

FIG. 10 is a cross sectional view of the exemplary structure of FIG. 9 after recessing the first electrically conductive via.

FIG. 11 is a cross sectional view of the exemplary structure of FIG. 10 after recessing the second liner and the first liner.

FIG. 12 is a cross sectional view of the exemplary structure of FIG. 11 after forming a second electrically conductive metal-containing layer on each of the recessed first electrically conductive via, recessed second liner, recessed first liner and on the topmost surface of the second ILD.

FIG. 13 is a cross sectional view of the exemplary structure of FIG. 12 after performing a planarization process to provide an exemplary semiconductor structure of the present application.

FIG. 14 is a cross sectional view of the exemplary structure of FIG. 9 after recessing the first electrically conductive via.

FIG. 15 is a cross sectional view of the exemplary structure of FIG. 14 after first recessing the second liner and the first liner.

FIG. 16 is a cross sectional view of the exemplary structure of FIG. 15 after second recessing the second liner.

FIG. 17 is a cross sectional view of the exemplary structure of FIG. 16 after forming a second electrically conductive metal-containing layer on each of the recessed first electrically conductive via, twice recessed second liner, recessed first liner and on the topmost surface of the second ILD.

FIG. 18 is a cross sectional view of the exemplary structure of FIG. 17 after performing a planarization process to provide another exemplary semiconductor structure of the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

For multi-level interconnection of advanced semiconductor devices, electrically conductive vias are used to enable metal-to-metal contact to the levels below. Electrically conductive vias typically include a main conductor material (i.e., metal) such as, for example, Cu, W or Co and several suitable nucleation layers, liners and/or barrier layers (such as, for example, TiN and/or TaN). These layers/liners ensure adequate adhesion to the surrounding ILD layer wall as well as good nucleation and growth of the main conductor material.

Liner and barrier materials typically exhibit high resistivity, and the presence of such high-resistivity liners and barrier layers in an electrically conductive via results in high via resistance which can negatively impact device performance. In addition, the various interfaces formed by these liners and barrier layers can add resistance components to the overall via resistance.

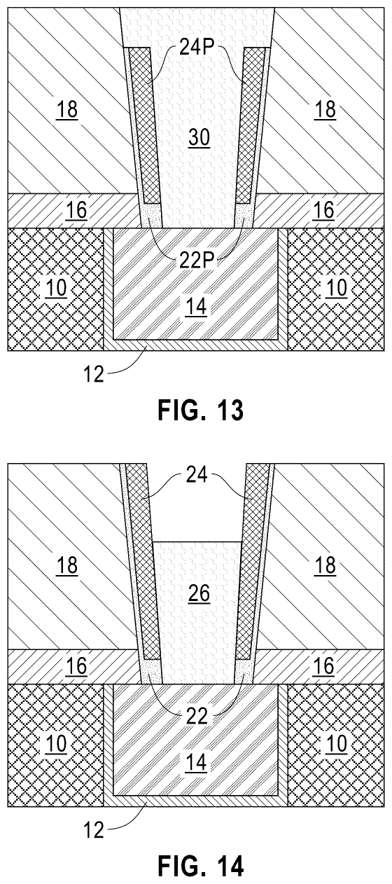

The present application provides an electrically conductive via in which the via resistance is reduced by forming a dual partial liner on a portion of, but not entirely covering, a sidewall of the electrically conductive via and by eliminating the complete coverage of a bottom wall of the electrically conductive via with any liner such that direct contact between the electrically conductive via and an underlying electrically conductive structure is established. Notably, the present application provides an interconnect structure as illustrated in FIGS. 13 and 18 that includes electrically conductive structure 14 embedded in first interlayer dielectric layer 10, electrically conductive via 30 embedded in second interlayer dielectric layer 18 in which the electrically conductive via 30 is in direct physical contact with the electrically conductive structure 14, and a dual partial liner located on a portion of a sidewall of the electrically conductive via 30. The dual partial liner includes first partial liner 22P and second partial liner 24P in which the first partial liner 22P extends under the second partial liner 24P and the electrically conductive via structure 30 extends over both the first partial liner 22P and the second partial liner 24P and contacts a sidewall of the second interlayer dielectric layer 18.

Referring now to FIG. 1, there is illustrated an exemplary structure that can be employed in the present application, the exemplary structure including an electrically conductive structure 14 embedded in a first ILD layer 10, and a dielectric cap 16 located on the first ILD layer 10 and the electrically conductive structure 14. In some embodiments and as is illustrated in FIG. 1, a diffusion barrier liner 12 can be present along a sidewall and a bottom wall of the electrically conductive structure 14. In other embodiments, the diffusion barrier liner 12 can be omitted. Collectively, the electrically conductive structure 14, the optional diffusion barrier liner 12 and the first ILD layer 10 provide a metal (or interconnect) level, Mₙ, wherein n is any integer starting from 1; the upper limit of ‘n’ can vary and can be predetermined by the manufacturer of a specific integrated circuit. Although the present application describes and illustrates a single electrically conductive structure 14 embedded in the first ILD layer 10, the present application contemplates embodiments in which more than one electrically conductive structure 14 is embedded in the first ILD layer 10. When more than one electrically conductive structure 14 is present in the first ILD layer 10, some or all of the electrically conductive structures can be processed to include a via structure including the dual partial liner described herein.

In some embodiments, the electrically conductive structure 14 can extend entirely through the first ILD layer 10. In other embodiments, the electrically conductive structure 14 extends partially through the first ILD layer 10 and in such embodiments, the electrically conductive structure 14 can be connected to another electrically conductive structure such as, for example, a metal line and/or a metal via, that can be located directly beneath, and in contact with, the electrically conductive structure 14.

Although not illustrated in any of the drawings of the present application, a substrate can be located beneath metal level, Mₙ. The substrate can include a front-end-of-the-line (FEOL) level including one or more semiconductor devices, such as, for example, field effect transistors located on a semiconductor material; a middle-of-the-line (MOL) level including a plurality of metal contact structures embedded in a MOL dielectric material layer; at least one lower interconnect level that includes a plurality of lower interconnect structures embedded in a lower interconnect dielectric material layer; or any combination thereof. In one example, the substrate includes a FEOL level and a MOL level.

The metal level, Mₙ, can be formed utilizing techniques that are known to those skilled in the art. In one embodiment, a damascene process can be used in forming metal level, Mₙ. A damascene process can include forming an opening into the first ILD layer 10, filling the opening with an optional diffusion barrier layer, and an electrically conductive material and, if needed performing a planarization process such as, for example, chemical mechanical polishing (CMP) to remove the optional diffusion barrier layer and the electrically conductive material from the topmost surface of the first ILD layer 10. The diffusion barrier layer that remains in the opening can be referred to herein as diffusion barrier liner 12, and the electrically conductive material that remains in the opening can be referred to herein as the electrically conductive structure 14. In some embodiments, and as shown in FIG. 1, the electrically conductive structure 14 has a topmost surface that is substantially coplanar with a topmost surface of the first ILD layer 10 as well as with a topmost surface of the diffusion barrier liner 12, if the same is present.

The first ILD layer 10 can be composed of a dielectric material such as, for example, silicon dioxide, silicon nitride, undoped silicate glass (USG), fluorosilicate glass (FSG), borophosphosilicate glass (BPSG), a spin-on low-k dielectric material, a chemical vapor deposition (CVD) low-k dielectric material or any combination thereof. The term “low-k” as used throughout the present application denotes a dielectric material that has a dielectric constant of less than 4.0. All dielectric constants mentioned herein as measured in a vacuum unless otherwise noted. Illustrative low-k dielectric materials that can be used as the first ILD layer 10 include, but are not limited to, silsesquioxanes, C doped oxides (i.e., organosilicates) that includes atoms of Si, C, O and H, thermosetting polyarylene ethers, or multilayers thereof. The term “polyarylene” is used in this application to denote aryl moieties or inertly substituted aryl moieties which are linked together by bonds, fused rings, or inert linking groups such as, for example, oxygen, sulfur, sulfone, sulfoxide, carbonyl and the like. Although not shown, the first ILD layer 10 can include a multilayered structure that includes at least two different dielectric materials stacked one atop the other. The first ILD layer 10 can be formed utilizing a deposition process including, for example, chemical vapor deposition (CVD), plasma enhanced chemical vapor deposition (PECVD), evaporation or spin-on coating.

The diffusion barrier layer (and thus the resultant diffusion barrier liner 12) that can optionally be employed in the present application includes a diffusion barrier material (i.e., a material that serves as a barrier to prevent a conductive material such as copper from diffusing there through). Examples of diffusion barrier materials that can be used in providing the diffusion barrier layer (and thus the resultant diffusion barrier liner 12) include, but are not limited to, Ta, TaN, Ti, TiN, Ru, RuN, RuTa, RuTaN, W, or WN; in some instances of the present application chemical symbols, as found in the Periodic Table of Elements, are used instead of the full names of the elements or compounds. In some embodiments, the diffusion barrier material can include a material stack of diffusion barrier materials. In one example, the diffusion barrier material can be composed of a stack of Ta/TaN. The diffusion barrier layer can be formed by a deposition process such as, for example, CVD, PECVD, or physical vapor deposition (PVD).

The electrically conductive material that provides the electrically conductive structure 14 can include an electrically conductive metal and/or an electrically conductive metal alloy. Illustrative examples of electrically conductive metals include, but are not limited to, Cu, W, Al, Co, or Ru. An illustrative example of an electrically conductive metal alloy includes Cu—Al alloy. The electrically conductive material that provides electrically conductive structure 14 can be formed by a deposition process such as, for example, CVD, PECVD, PVD, sputtering or electroplating. In some embodiments, a reflow anneal can follow the deposition of the electrically conductive material that provides electrically conductive structure 14. The electrically conductive structure 14 can be a metal line, a metal via or a combination of a metal line/metal via.

After forming the metal level, Mₙ, dielectric cap 16 is formed. Dielectric cap 16 is composed of a dielectric capping material which is compositionally different from the dielectric material that provides the first ILD layer 10. The dielectrically capping material that provides the dielectric cap 16 can include, but is not limited to, silicon nitride (SiN), or a dielectric containing atoms of silicon, nitrogen and carbon (i.e., SiNC). The dielectric cap 16 can be formed by a deposition process including, but not limited to, atomic layer deposition (ALD), CVD, PECVD or PVD.

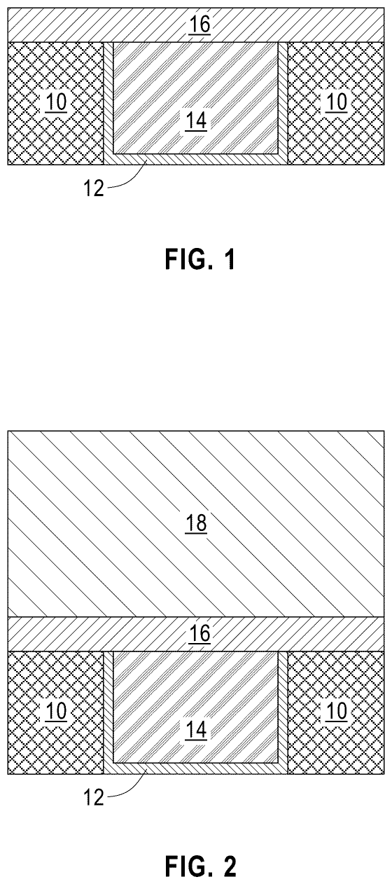

Referring now to FIG. 2, there is illustrated the exemplary structure of FIG. 1 after forming a second ILD layer 18 on the dielectric cap 16. The second ILD layer 18 can include a dielectric material as mentioned above for the first ILD layer 10. The dielectric material that provides the second ILD layer 18 can be compositionally the same as, or compositionally different from, the dielectric material that provides the first ILD layer 10. The dielectric material that provides the second ILD layer 18 is however compositionally different from the dielectric capping material that provides the dielectric cap 16. The dielectric cap 16 thus can be used as an etch stop layer during the subsequent formation of the via opening 20 as shown in FIG. 3. The second ILD layer 18 can be formed by a deposition process such as, for example, CVD, PECVD, evaporation or spin-on coating. A planarization process such as, for example, CMP, can follow the deposition of the dielectric material that provides the second ILD layer 18.

Referring now to FIG. 3, there is illustrated the exemplary structure of FIG. 2 after forming a via opening 20 in the second ILD layer 18. The via opening 20 extends through an entirety of the second ILD layer 18 and physically exposes a portion of dielectric cap 16. The via opening 20 can be formed by lithographic patterning. Lithographic patterning includes forming a photoresist material on a layer/multilayered stack that needs to be patterned, exposing the as deposited photoresist material to a desired pattern of irradiation, developing the photoresist material and transferring the pattern from the developed photoresist material into the layer/multilayered stack that needs to be patterned, the transferring of the pattern can include one or more etching processes. The one or more etching processes can include dry etching and/or wet etching. Dry etching can include reactive ion etching (RIE), plasma etching or ion beam etching. Wet etching can include the use of a chemical etchant that is selective in removing physically exposed portions of the layer/multilayered stack that needs to be patterned. The photoresist material is removed after the pattern transfer process utilizing a material removal process that is selective in removing the photoresist material. In some embodiments of the present application and as is illustrated in FIG. 3, the via opening 20 can have tapered sidewalls in which the width of the via opening 20 decreases in a direction from the top of the via opening 20 to the bottom of the via opening 20. In other embodiments (not shown), the via opening 20 can have substantially perpendicular sidewalls.

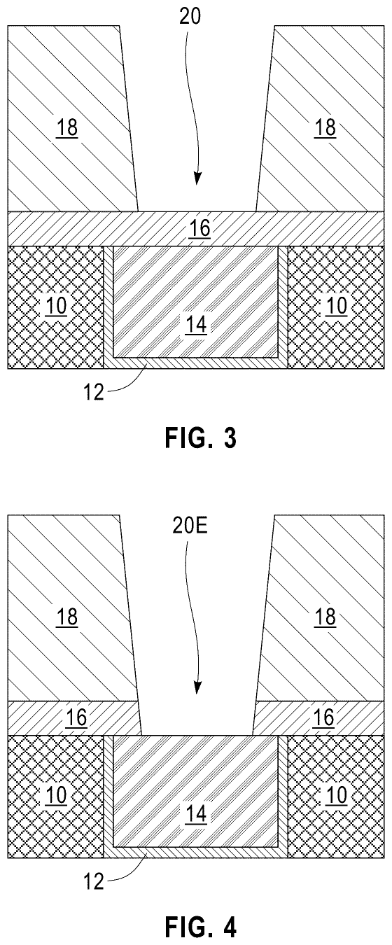

Referring now to FIG. 4, there is illustrated the exemplary structure of FIG. 3 after performing a dielectric cap punch through etch to extend the via opening 20 such that an extended via opening 20E is formed that physically exposes a portion of the electrically conductive structure 14. The dielectric cap punch through etch includes an etching process such as, for example, RIE, that is selective in removing the dielectric capping material that provides the dielectric cap 16. The dielectric cap punch through etch opens the dielectric cap 16 and stops on a surface of the electrically conductive structure 14. In some embodiments and as is shown in FIG. 4, the extended via opening 20E can have tapered sidewalls in which the width of the extended via opening 20E decreases in a direction from the top of the extended via opening 20E to the bottom of the extended via opening 20E. In other embodiments (not shown), the extended via opening 20E can have substantially perpendicular sidewalls.

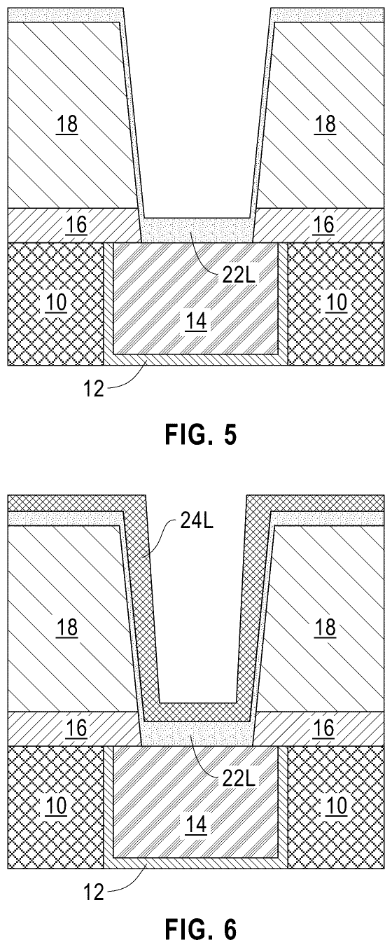

Referring now to FIG. 5, there is illustrated the exemplary structure of FIG. 4 after depositing a first liner material layer 22L in the extended via opening 20E and on a topmost surface of the second ILD layer 18. The first liner material layer 22L is composed of a first liner material including, for example, Ta, TaN, TaWN, Ti, TiN, Ru, RuN, RuTa, RuTaN, W, or WN. The first liner material layer 22L can be formed by a deposition process such as, for example, CVD, PECVD, ALD or PVD. The first liner material layer 22L can be a conformal layer (not illustrated in the present application) or a non-conformal layer (as illustrated in FIG. 5). As used herein, the term “conformal layer” denotes that a material layer has a vertical thickness along horizontal surfaces that is substantially the same (i.e., within ±5%) as the lateral thickness along vertical surfaces. As is illustrated in FIG. 5, the first liner material layer 22L is in direct physical contact with the exposed portion of the electrically conductive structure 14.

Referring now to FIG. 6, there is illustrated the exemplary structure of FIG. 5 after depositing a second liner material layer 24L on the first liner material layer 22L. The second liner material layer 24L is composed of a second liner material. The second liner material that provides the second liner material layer 24L is compositionally different from the first liner material that provides the first liner material layer 22L. Examples of second dielectric liner materials that can be employed include, but are not limited to, Ta, TaN, TaWN, Ti, TiN, Ru, RuN, RuTa, RuTaN, W, or WN. In one example, the first dielectric liner material that provides the first dielectric liner material layer 22L is composed of TaN, while the second dielectric liner material that provides the second dielectric liner material layer 24L is composed of TaWN. The second liner material layer 24L can be formed by a deposition process such as, for example, CVD, PECVD, ALD or PVD. The second liner material layer 24L can be a conformal layer (as illustrated in FIG. 6) or a non-conformal layer (not illustrated in the present application). It is noted that neither the first liner material layer 22L, nor the second liner material layer 24L fills in an entirety of the extended via opening 20E.

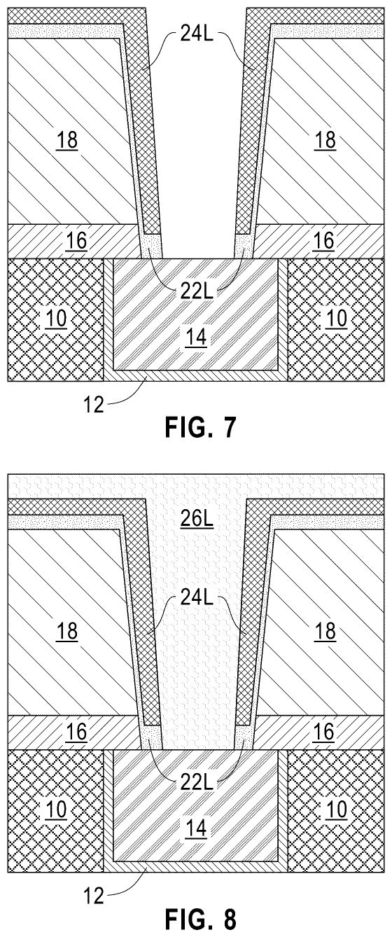

Referring now to FIG. 7, there is illustrated the exemplary structure of FIG. 6 after performing an etch back process on the second liner material layer 24L and the first liner material layer 22L to re-expose a portion of the electrically conductive structure 14. The etch back process can include, for example, RIE or a wet etch process. The etch back process removes the second liner material layer 24L and the first liner material layer 22L that are located at the bottommost portion of the extended via opening 20E and thus opens both the second liner material layer 24L and the first liner material layer 22L as is illustrated in FIG. 7. The etch back process can be aided by forming a block mask (not shown) over areas of the exemplary structure in which removal of the second liner material layer 24L and the first liner material layer 22L are not desirable. The block mask is removed after the etch back process utilizing a material removal process that is selective in removing the block mask.

Referring now to FIG. 8, there is illustrated the exemplary structure of FIG. 7 after depositing a first electrically conductive metal-containing layer 26L in the extended via opening 20E and above the topmost surface of the second ILD layer 18. The first electrically conductive metal-containing layer 26L is in direct physical contact with the second liner material layer 22L and with the re-exposed portion of the electrically conductive structure 14. The first electrically conductive metal-containing layer 26L is composed of an electrically conductive metal or an electrically conductive metal alloy, as defined above. The first electrically conductive metal-containing layer 26L can be compositionally the same as, or compositionally different from, the electrically conductive structure 14. The first electrically conductive metal-containing layer 26L can be formed by a deposition process such as, for example, CVD, PECVD, PVD, sputtering or platting. In some embodiments, a reflow anneal can follow the deposition of the electrically conductive material that provides first electrically conductive metal-containing layer 26L.

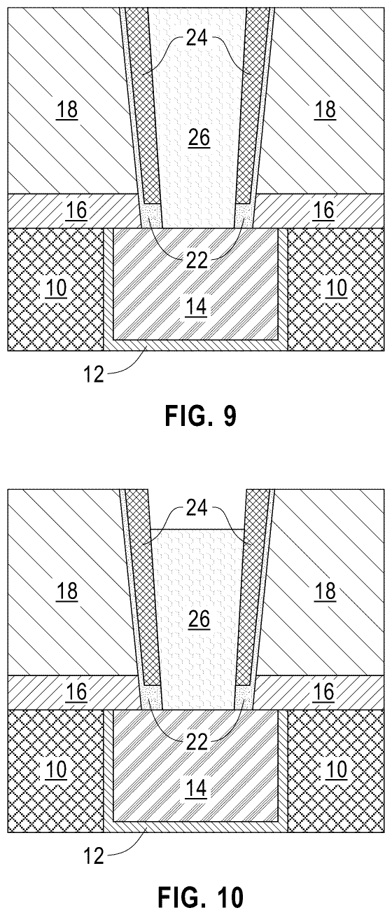

Referring now to FIG. 9, there is illustrated the exemplary structure of FIG. 8 after performing a planarization process to remove the first electrically conductive metal-containing layer 26L, the second liner material layer 24L and the first liner material layer 22L from above the topmost surface of the second ILD layer 18 and to provide a first electrically conductive via 26, a second liner 24 and a first liner 22, respectively in the extended via opening 20E. The planarization can include CMP. The planarization process provides a planar multi-component structure of the first electrically conductive via 26, second liner 24 and first liner 22 in the extended via opening 20E in which a topmost surface of the first electrically conductive via 26 is substantially coplanar with a topmost surface of each of the second liner 24, first liner 22 and the second ILD layer 18. As is illustrated in FIG. 9, the first electrically conductive via 26 is in direct physical contact with the electrically conductive structure 14 as well as with an inner sidewall of the second liner 24 and a bottommost portion of an inner sidewall of the first liner 22 that is present beneath (i.e., extends under) the second liner 24.

Referring now to FIG. 10, there is illustrated the exemplary structure of FIG. 9 after recessing the first electrically conductive via 26. The recessing of the first electrically conductive via 26 can be performed utilizing a recess etch that is selective in recessing the first electrically conductive via 26. The recess etch removes an upper portion of the first electrically conductive via 26 such that the first electrically conductive via 26 that remains after the recessing has a topmost surface that is no longer coplanar with the second liner 24, the first liner 22 and the second ILD layer 18.

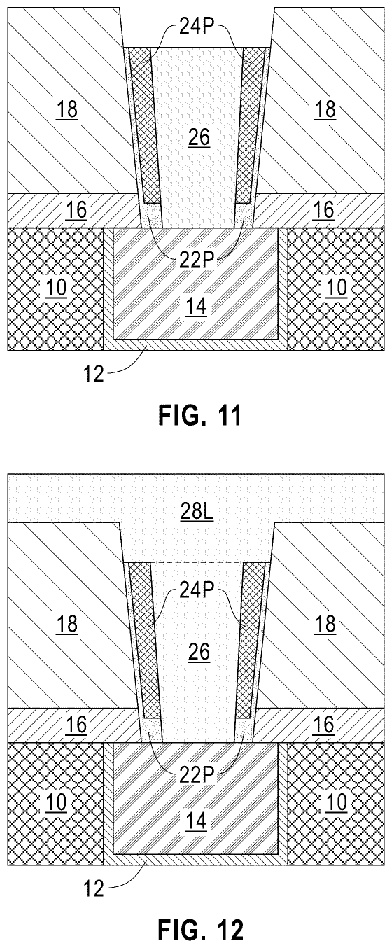

Referring now to FIG. 11, there is illustrated the exemplary structure of FIG. 10 after recessing the second liner 24 and the first liner 22. The recessing of the second liner 24 and the first liner 22 can be performed utilizing one or more recess etching processes that is (are) selective in recessing the second liner 24 and the first liner 22. In one example, a wet etching process is used in recessing the second liner 24 and the first liner 22. The one or more recess etching processes removes an upper portion of the second liner 24 and an upper portion of the first liner 22 such that the second liner 24 and the first liner 22 that remain after the recessing have topmost surfaces that are no longer coplanar with the second ILD layer 18. The second liner 24 that remains after the recessing has a topmost surface that is substantially coplanar with a topmost surface of the first liner 22 that remains after the recessing. The second liner 24 and the first liner 22 that remain after the recessing have topmost surfaces that are substantially coplanar with the first electrically conductive via 26 that remains after recessing the first electrically conductive via 26. The second liner 24 that remains after the recessing can be referred to herein as second partial liner 24P, while the first liner 22 that remains after the recessing can be referred to herein as first partial liner 22P. In the present application, a bottom portion of the first partial liner 22P that extends beneath the second partial liner 24P has a width that is greater than a width of the first partial liner 22P that extends along a sidewall of the second partial liner 24P.

Referring now to FIG. 12, there is illustrated the exemplary structure of FIG. 11 after forming a second electrically conductive metal-containing layer 28L on each of the recessed first electrically conductive via 26, second partial liner 24P, first partial liner 22P and on the topmost surface of the second ILD 18. The second electrically conductive metal-containing layer 28L is composed of an electrically conductive metal or an electrically conductive metal alloy, as defined above. The second electrically conductive metal-containing layer 28L can be compositionally the same as, or compositionally different than, the first electrically conductive metal-containing layer 26L. In the drawing, a dotted line is shown to represent a hypothetical material interface that can exists between the second electrically conductive metal-containing layer 28L and the first electrically conductive metal-containing layer 26L. The material interface is present when the second electrically conductive metal-containing layer 28L and the first electrically conductive metal-containing layer 26L are composed of compositionally different electrically conductive materials. No such material interface would be present when the second electrically conductive metal-containing layer 28L and the first electrically conductive metal-containing layer 26L are composed of compositionally same electrically conductive materials. The second electrically conductive metal-containing layer 28L can be formed by a deposition process such as, for example, CVD, PECVD, PVD, sputtering or electroplating.

Referring now to FIG. 13, there is illustrated the exemplary structure of FIG. 12 after performing a planarization process such as, for example, CMP, to provide an exemplary semiconductor structure of the present application. The planarization process removes an upper portion of the second electrically conductive metal-containing layer 28L that is located outside of the extended via opening 20E and on a topmost surface of the second ILD layer 18, while maintaining a lower portion of the second electrically conductive metal-containing layer 28L in the extended via opening 20E. The planarization process shown in FIG. 13 provides an electrically conductive via 30 that includes a remaining portion of the second electrically conductive metal-containing layer 28L and the first electrically conductive via 26. In the drawing, these two components/elements of the electrically conductive via 30 are not individually shown but both are included in the region defined as the electrically conductive via 30. As is illustrated, the electrically conductive via 30 has a topmost surface that is substantially coplanar with a topmost surface of the second ILD layer 18 and a bottommost surface that is in direct physical contact with a portion of the first electrically conductive structure 14. As is further shown in FIG. 13, an upper portion of the electrically conductive via 30 is in direct physical contact with a topmost surface of each of the first partial liner 22P and the second partial liner 24P. The electrically conductive via 30 is also in direct physical contact with the inner sidewall of the second partial liner 24P and the inner sidewall of the first partial liner 22P that extends beneath the second partial liner 24P as well as with a sidewall of the second ILD layer 18. In this embodiment, the second partial liner 24P has a topmost surface that is substantially coplanar with a topmost surface of the first partial liner 22P, yet the topmost surfaces of both the second partial liner 24P and the first partial liner 22P are vertically offset from, and located beneath, the topmost surface of the electrically conductive via 30 and the topmost surface of the second ILD layer 18. Also, and as illustrated in FIG. 13, the second partial liner 22P is in direct contact with the electrically conductive structure 14 and the second partial liner 24P is entirely separated from the electrically conductive structure 14 by the first partial liner 22P. It is noted that the electrically conductive via 30 and the dual partial liner extends through the dielectric cap 16.

Notably, FIG. 13 illustrates an interconnect structure in accordance with an embodiment of the present application. The interconnect structure illustrated in FIG. 13 includes electrically conductive structure 14 embedded in first interlayer dielectric layer 10, electrically conductive via 30 embedded in second interlayer dielectric layer 18 in which the electrically conductive via 30 is in direct physical contact with the electrically conductive structure 14, and a dual partial liner located on a portion of a sidewall of the electrically conductive via 30. In this embodiment, the dual partial liner includes first partial liner 22P and a second partial liner 24P in which the first partial liner 22P extends under the second partial liner 24P and has a topmost surface that is substantially coplanar with a topmost surface of the second partial liner 26P.

Referring now to FIG. 14, there is illustrated the exemplary structure of FIG. 9 after recessing the first electrically conductive via 26. The recessing of the first electrically conductive via 26 used in this embodiment of the present application is the same as that mentioned above in regard to providing the exemplary structure shown in FIG. 10. In this embodiment, more of the first electrically conductive via 26 is typically removed as compared to that shown in FIG. 10.

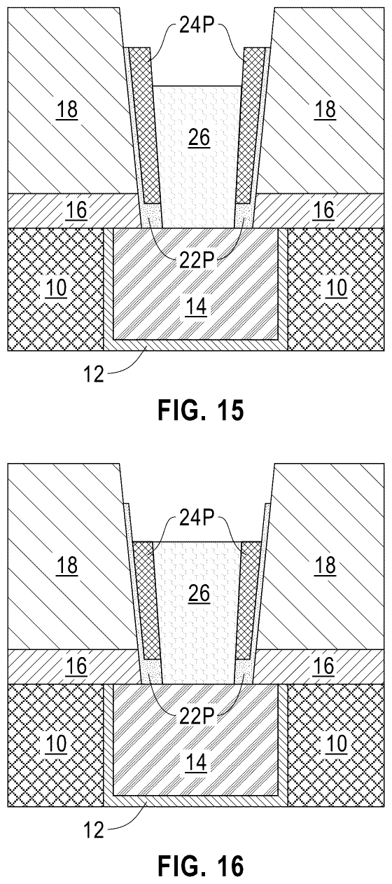

Referring now to FIG. 15, there is illustrated the exemplary structure of FIG. 14 after first recessing the second liner 24 and the first liner 22. The first recessing of the second liner 24 and the first liner 22 can be performed utilizing one or more recess etching processes as mentioned above in recessing the second liner 24 and the first liner 22 in the previous embodiment of the present application. See, for example, the description above regarding the recessing of the second liner 24 and the first liner 22 with respect to providing the exemplary structure shown in FIG. 11. The second liner 24 that remains after the recessing can be referred to herein as second partial liner 24P, while the first liner 22 that remains after the recessing can be referred to herein as first partial liner 22P. At this point of the present application, the second partial liner 24P has a topmost surface that is substantially coplanar with a topmost surface of the first partial liner 22P. Also and as illustrated in FIG. 15, the substantially coplanar topmost surfaces of the second partial liner 24P and the first partial liner 22P are vertical offset and located above a topmost surface of the recessed first electrically conductive via 26.

Referring now to FIG. 16, there is illustrated the exemplary structure of FIG. 15 after recessing the second partial liner 24P. The recessing of the second partial liner 24P includes a recess etching process that is selective in removing an upper portion of the second partial liner 24P as compared to the first partial liner 22P. The second partial liner 24P that remains after this recessing step has a topmost surface that is now vertically offset and located beneath a topmost surface of the first partial liner 22P. The topmost surface of the second partial liner 24P that remains after this recessing step can be substantially coplanar with a topmost surface of the recessed first electrically conductive via 26.

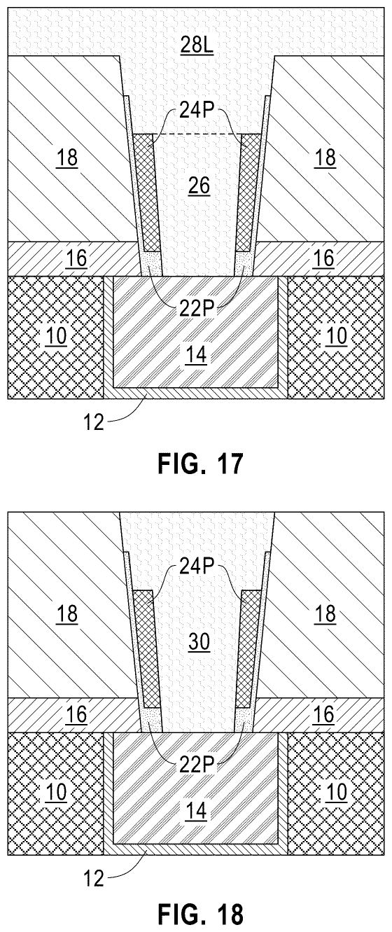

Referring now to FIG. 17, there is illustrated the exemplary structure of FIG. 16 after forming a second electrically conductive metal-containing layer 28L on each of the recessed first electrically conductive via 26, twice recessed second liner 24L (i.e., second partial liner 24P), recessed first liner 22L (i.e., first partial liner 22P) and on the topmost surface of the second ILD 18. The second electrically conductive metal-containing layer 28L of this embodiment is the same as the second electrically conductive metal-containing layer 28L described above with respect to providing the exemplary structure shown in FIG. 12.

Referring now to FIG. 18, there is illustrated the exemplary structure of FIG. 17 after performing a planarization process such as, for example, CMP, to provide another exemplary semiconductor structure of the present application. The planarization process removes an upper portion of the second electrically conductive metal-containing layer 28L that is located outside of the extended via opening 20E and on a topmost surface of the second ILD layer 18, while maintaining a lower portion of the second electrically conductive metal-containing layer 28L in the extended via opening 20E. The planarization process shown in FIG. 18 provides an electrically conductive via 30 that includes a remaining portion of the second electrically conductive metal-containing layer 28L and the first electrically conductive via 26. In the drawing, these two components/elements of the electrically conductive via 30 are not individually shown but both are included in the region defined as the electrically conductive via 30. As is illustrated, the electrically conductive via 30 has a topmost surface that is substantially coplanar with a topmost surface of the second ILD layer 18 and a bottommost surface that is in direct physical contact with a portion of the first electrically conductive structure 14. As is further shown in FIG. 18, an upper portion of the electrically conductive via 30 is in direct physical contact with a topmost surface of each of the first partial liner 22P and the second partial liner 24P. The electrically conductive via 30 is also in direct physical contact with the inner sidewall of the second partial liner 24P and the inner sidewall of the first partial liner 22P that extends beneath the second partial liner 24P and above the second partial liner 24P as well as with a sidewall of the second ILD layer 18. In this embodiment, the second partial liner 24P has a topmost surface that is vertically offset and located below a topmost surface of the first partial liner 22P, yet the topmost surfaces of both the second partial liner 24P and the first partial liner 22P are vertically offset from the topmost surface of the electrically conductive via 30 and the topmost surface of the second ILD layer 18. Also, and as illustrated in FIG. 18, the first partial liner 22P is in direct contact with the electrically conductive structure 14 and the second partial liner 24P is entirely separated from the electrically conductive structure 14 by the first partial liner 22P. It is noted that the electrically conductive via 30 and the dual partial liner extends through the dielectric cap 16.

Notably, FIG. 18 illustrates an interconnect structure in accordance with an embodiment of the present application. The interconnect structure illustrated in FIG. 18 includes electrically conductive structure 14 embedded in first interlayer dielectric layer 10, electrically conductive via 30 embedded in second interlayer dielectric layer 18 in which the electrically conductive via 30 is in direct physical contact with the electrically conductive structure 14, and a dual partial liner located on a portion of a sidewall of the electrically conductive via 30. In this embodiment, the dual partial liner includes first partial liner 22P and a second partial liner 24P in which the first partial liner 22P extends under the second partial liner 24P and has a topmost surface that is vertically offset and located above a topmost surface of the second partial liner 24P.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. An interconnect structure comprising:
an electrically conductive structure embedded in a first interlayer dielectric layer;
an electrically conductive via embedded in a second interlayer dielectric layer, wherein the electrically conductive via is in direct physical contact with the electrically conductive structure; and
a dual partial liner located on a portion of a sidewall of the electrically conductive via, wherein the dual partial liner comprises a first partial liner and a second partial liner, wherein the first partial liner extends under the second partial liner and the electrically conductive via structure extends over both the first partial liner and the second partial liner and contacts a sidewall of the second interlayer dielectric layer.

2. The interconnect structure of claim 1, wherein the first partial liner has a topmost surface that is substantially coplanar with a topmost surface of the second partial liner.

3. The interconnect structure of claim 1, wherein the first partial liner has a topmost surface that is vertically offset and located above a topmost surface of the second partial liner.

4. The interconnect structure of claim 1, wherein the electrically conductive via has a topmost surface that is substantially coplanar with a topmost surface of the second interlayer dielectric layer.

5. The interconnect structure of claim 1, wherein the first partial liner is in direct contact with the electrically conductive structure and the second partial liner is entirely separated from the electrically conductive structure by the first partial liner.

6. The interconnect structure of claim 1, wherein the electrically conductive via contacts an inner sidewall of both the second partial liner and the first partial liner.

7. The interconnect structure of claim 1, further comprising a dielectric cap located between the first interlayer dielectric layer and the second interlayer dielectric layer, wherein the electrically conductive via and the dual partial liner extend through the dielectric cap.

8. The interconnect structure of claim 1, wherein a bottom portion of the first partial liner that extends beneath the second partial liner has a width that is greater than a width of the first partial liner that extends along a sidewall of the second partial liner.

9. An interconnect structure comprising:
an electrically conductive structure embedded in a first interlayer dielectric layer;
an electrically conductive via embedded in a second interlayer dielectric layer, wherein the electrically conductive via is in direct physical contact with the electrically conductive structure; and
a dual partial liner located on a portion of a sidewall of the electrically conductive via, wherein the dual partial liner comprises a first partial liner and a second partial liner, wherein the first partial liner extends under the second partial liner and has a topmost surface that is substantially coplanar with a topmost surface of the second partial liner.

10. The interconnect structure of claim 9, wherein the electrically conductive via extends above the topmost surface of the first partial liner and the second partial liner and is in direct physical contact with a sidewall of the second interlayer dielectric layer, and the electrically conductive via has a topmost surface that is substantially coplanar with a topmost surface of the second interlayer dielectric layer.

11. The interconnect structure of claim 9, wherein the first partial liner is in direct contact with the electrically conductive structure and the second partial liner is entirely separated from the electrically conductive structure by the first partial liner.

12. The interconnect structure of claim 9, wherein the electrically conductive via contacts an inner sidewall of both the second partial liner and the first partial liner.

13. The interconnect structure of claim 9, further comprising a dielectric cap located between the first interlayer dielectric layer and the second interlayer dielectric layer, wherein the electrically conductive via and the dual partial liner extend through the dielectric cap.

14. The interconnect structure of claim 9, wherein a bottom portion of the first partial liner that extends beneath the second partial liner has a width that is greater than a width of the first partial liner that extends along a sidewall of the second partial liner.

15. An interconnect structure comprising:
an electrically conductive structure embedded in a first interlayer dielectric layer;
an electrically conductive via embedded in a second interlayer dielectric layer, wherein the electrically conductive via is in direct physical contact with the electrically conductive structure; and
a dual partial liner located on a portion of a sidewall of the electrically conductive via wherein the dual partial liner comprises a first partial liner and a second partial liner, wherein the first partial liner extends under the second partial liner and has a topmost surface that is vertically offset and located above a topmost surface of the second partial liner.

16. The interconnect structure of claim 15, wherein the electrically conductive via extends above the topmost surface of the first partial liner and the second partial liner and is in direct physical contact with a sidewall of the second interlayer dielectric layer, and the electrically conductive via has a topmost surface that is substantially coplanar with a topmost surface of the second interlayer dielectric layer.

17. The interconnect structure of claim 15, wherein the first partial liner is in direct contact with the electrically conductive structure and the second partial liner is entirely separated from the electrically conductive structure by the first partial liner.

18. The interconnect structure of claim 15, wherein the electrically conductive via contacts a sidewall of both the second partial liner and the first partial liner.

19. The interconnect structure of claim 15, further comprising a dielectric cap located between the first interlayer dielectric layer and the second interlayer dielectric layer, wherein the electrically conductive via and the dual partial liner extend through the dielectric cap.

20. The interconnect structure of claim 15, wherein a bottom portion of the first partial liner that extends beneath the second partial liner has a width that is greater than a width of the first partial liner that extends along a sidewall of the second partial liner.
